(19) United States
(12) Patent Application Publication
(10) Pub. No.: US 2019/0319153 A1
(43) Pub. Date: Oct. 17, 2019

(54) SOLAR CELL INCLUDING CONDUCTIVE AMORPHOUS SEMICONDUCTOR LAYER AND METHOD OF MANUFACTURING SOLAR CELL

(71) Applicant: Panasonic Intellectual Property Management Co., Ltd., Osaka (JP)

(72) Inventors: Daiki WATANABE, Osaka (JP); Hiroyuki YAMADA, Osaka (JP); Minato SENO, Osaka (JP); Akinori TSURUTA, Osaka (JP)

(21) Appl. No.: 16/447,737

(22) Filed: Jun. 20, 2019

Related U.S. Application Data
(63) Continuation of application No. PCT/JP2017/043091, filed on Nov. 30, 2017.

(30) Foreign Application Priority Data
Dec. 21, 2016 (JP) 2016-248504

(51) Int. Cl. H01L 31/0747; H01L 31/0224; H01L 31/18

(52) U.S. Cl. CPC H01L 31/0747; H01L 31/184; H01L 31/1804; H01L 31/022466

(57) ABSTRACT

An i-type layer is formed on a side of one surface of a crystalline semiconductor substrate. An n-type layer or a p-type layer is formed on the i-type layer and includes a conductive impurity. A TCO is formed on the n-type layer or the p-type layer. A density in a proximate portion of the n-type layer or the p-type layer closer to the TCO than a remote portion of the n-type layer or the p-type layer is smaller than a density in the remote portion.

### CROSS-REFERENCE TO RELATED APPLICATION

This application is based upon and claims the benefit of priority from the prior Japanese Patent Application No. 2016-248504, filed on Dec. 21, 2016, the entire contents of which are incorporated herein by reference.

### BACKGROUND

### 1. Field

The present disclosure relates to a solar cell including a conductive amorphous semiconductor layer and a method of manufacturing the solar cell.

### 2. Description of the Related Art

A diffusion potential is formed in a hetero-junction solar cell by depositing, on a substrate surface made of crystalline silicon, an amorphous silicon-based thin film having a band gap different from that of the substrate. In a hetero-junction solar cell like this, contact resistance is present at a junction interface between a translucent conductive film layer and p-type and n-type amorphous silicon-based thin films. This increases a series resistance of solar cells and makes it difficult to improve the photoelectric conversion efficiency. To address this, a p-type silicon oxide layer is interposed in a junction interface portion located between the p-type amorphous silicon-based thin film and the translucent conductive film (see, for example, JP2014-67901).

Generally, a larger current flows in a hetero-junction solar cell than in a thin-film solar cell. Therefore, the impact of contact resistance in a hetero-junction solar cell is larger than in a thin-film solar cell. If this issue is addressed by interposing a p-type silicon oxide layer to reduce the contact resistance, a step of forming a p-type silicon oxide on the p-type amorphous silicon-based thin film should be added.

### SUMMARY

The disclosure addresses the above-described issue, and a general purpose thereof is to provide a technology of reducing the contact resistance in a solar cell without producing an oxide film.

A solar cell according to an embodiment of the present disclosure includes: a crystalline semiconductor substrate; an intrinsic amorphous semiconductor layer formed on a side of one surface of the crystalline semiconductor substrate; a conductive amorphous semiconductor layer formed on the intrinsic amorphous semiconductor layer and including a conductive impurity; and a transparent conductive film layer formed on the conductive amorphous semiconductor layer. A density in a second portion of the conductive amorphous semiconductor layer closer to the transparent conductive film layer than a first portion of the conductive amorphous semiconductor layer is smaller than a density in the first portion.

Another embodiment of the present disclosure relates to a method of manufacturing a solar cell. The method includes: forming an intrinsic amorphous semiconductor layer on a side of one surface of a crystalline semiconductor substrate masked at least in part; forming a conductive amorphous semiconductor layer including a conductive impurity on the intrinsic amorphous semiconductor layer; and forming a transparent conductive film layer on the conductive amorphous semiconductor layer. A deposition speed for forming a second portion of the conductive amorphous semiconductor layer closer to the transparent conductive film layer than a first portion of the conductive amorphous semiconductor layer is higher than a deposition speed for forming the first portion.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a plan view of a solar cell module according to an embodiment of the present disclosure;

FIG. 2 is a cross-sectional view of the solar cell module of FIG. 1;

FIG. 3 is a plan view of the solar cell of FIG. 1 as viewed from the light receiving surface side;

FIG. 4 is a cross-sectional view of the solar cell of FIG. 3;

FIGS. 5A-5C are graphs showing density distribution and dopant concentration distribution in the p-type layer and the n-type layer of FIG. 4; and

FIGS. 6A-6C show an outline of the steps of manufacturing the solar cell of FIG. 4.

### DETAILED DESCRIPTION

The invention will now be described by reference to the preferred embodiments. This does not intend to limit the scope of the present invention, but to exemplify the invention.

A brief summary will be given before describing the disclosure in specific details. An embodiment of the disclosure relates to a plurality of solar cells (e.g., hetero-junction solar cells) included in a solar cell module. In a hetero-junction solar cell, an intrinsic amorphous semiconductor layer, a p-type amorphous semiconductor layer, and a transparent conductive film layer are stacked successively on the side of one surface of a crystalline semiconductor substrate and an intrinsic amorphous semiconductor layer, an n-type amorphous semiconductor layer, and a transparent conductive film layer are stacked successively on the side of the opposite surface of the crystalline semiconductor substrate. In a configuration like this, contact resistance is present between the p-type amorphous semiconductor layer and the transparent conductive film layer adjacent to each other, and contact resistance is also present between the n-type amorphous semiconductor layer and the transparent conductive film layer adjacent to each other. Contact resistance increases the series resistance of solar cells and so is required to be reduced.

The n-type amorphous semiconductor layer in the solar cell according to the embodiment has a two-layer structure in the direction of thickness of the solar cell. The two-layer structure includes a portion of the n-type amorphous semiconductor layer (hereinafter, referred to as “proximate portion”) closer to the transparent conductive film layer and a portion (hereinafter, referred to as “remote portion”) farther away from the transparent conductive film layer than the proximate portion. The density in the proximate portion is configured to be smaller than the density in the remote portion. The density is exemplified by atomic density. For this reason, the proximate portion is populated by a larger number of defects in which silicon atoms are not found where they should be than in the remote portion. An increase in the defect density results in an increase in the defect level. This increases the likelihood of electric conduction induced by the defect level. With a structure such as this, the contact resistance is reduced without using an oxide film, which causes reduction in the conductivity. The p-type amorphous semiconductor layer also has a two-layer structure. The terms “parallel” and “orthogonal” in the following description not only encompass completely parallel or orthogonal but also encompass slightly off-parallel within the margin of error. The term “substantially” means identical within certain limits.

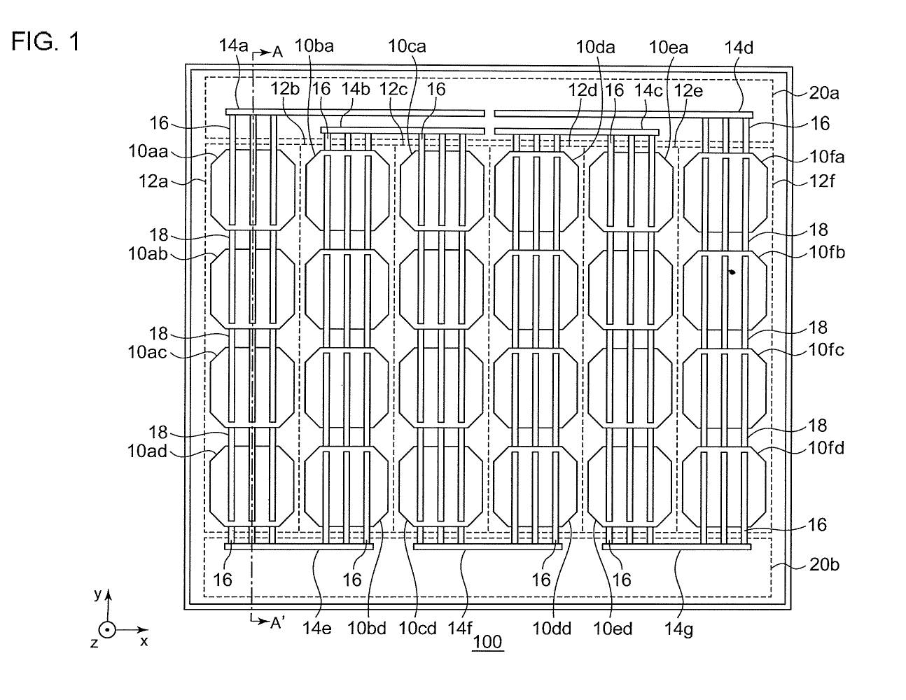

FIG. 1 is a plan view of a solar cell module 100 according to an embodiment of the present disclosure as viewed from a light receiving surface side. As shown in FIG. 1, an orthogonal coordinate system formed by an x axis, y axis, and a z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1, and the negative directions are defined in the directions opposite to those of the arrows. Of the two principal surfaces forming the solar cell module 100 that are parallel to the x-y plane, the principal surface disposed on the positive direction side along the z axis is the light receiving surface, and the principal surface disposed on the negative direction side along the z axis is the back surface. Hereinafter, the positive direction side along the z axis will be referred to as “light receiving surface side” and the negative direction side along the z axis will be referred to as “back surface side”.

The solar cell module 100 includes an 11th solar cell 10aa, . . . , a 64th solar cell 10fd, which are generically referred to as solar cells 10, a first bridge wiring member 14a, a second bridge wiring member 14b, a third bridge wiring member 14c, a fourth bridge wiring member 14d, a fifth bridge wiring member 14e, a sixth bridge wiring member 14f, a seventh bridge wiring member 14g, which are generically referred to as bridge wiring members 14, a cell end wiring member 16, and an inter-cell wiring member 18. A first non-generating area 20a and a second non-generating area 20b are disposed to sandwich the plurality of solar cells 10 in the y axis direction. More specifically, the first non-generating area 20a is disposed farther on the positive direction side along the y axis than the plurality of solar cells 10, and the second non-generating area 20b is disposed further on the negative direction side along the y axis than the plurality of solar cells 10. The first non-generating area 20a and the second non-generating area 20b (hereinafter, sometimes generically referred to as “non-generating areas 20”) have a rectangular shape and do not include the solar cells 10.

Each of the plurality of solar cells 10 absorbs incident light and generates photovoltaic power. The solar cell 10 is made of, for example, a semiconductor material such as crystalline silicon, gallium arsenide (GaAs), or indium phosphorus (InP). The structure of the solar cell 10 will be described later. It will be assumed here that the solar cell 10 is a hetero-junction solar cell as described above. In a hetero-junction solar cell, crystalline silicon and amorphous silicon are stacked. A plurality of finger electrodes extending in the x axis direction in a mutually parallel manner and a plurality of (e.g., three) bus bar electrodes extending in the y axis direction to be orthogonal to the plurality of finger electrodes are disposed on the light receiving surface and the back surface of each solar cell 10 although the finger electrodes and the bus bar electrodes are omitted in FIG. 1. The bus bar electrodes connect the plurality of finger electrodes to each other. The bus bar electrodes and the finger electrodes are formed by, for example, silver paste or the like.

The plurality of solar cells 10 are arranged in a matrix on the x-y plane. By way of example, six solar cells 10 are arranged in the x axis direction and four solar cells are arranged in the y axis direction. The number of solar cells 10 arranged in the x axis direction and the number of solar cells 10 arranged in the y axis direction are not limited to the examples above. The four solar cells 10 arranged and disposed in the y axis direction are connected in series by the inter-cell wiring member 18 so as to form one solar cell string 12. For example, by connecting the 11th solar cell 10aa, a 12th solar cell 10ab, a 13th solar cell 10ac, and a 14th solar cell 10ad, a first solar cell string 12a is formed. The other solar cell strings 12 (e.g., a second solar cell string 12b through a sixth solar cell string 12f) are similarly formed. As a result, the six solar cell strings 12 are arranged in parallel in the x axis direction.

In order to form the solar cell strings 12, the inter-cell wiring members 18 connect the bus bar electrode on the light receiving surface side of one of adjacent solar cells 10 to the bus bar electrode on the back surface side of the other solar cell 10. For example, the three inter-cell wiring members 18 for connecting the 11th solar cell 10aa and the 12th solar cell 10ab electrically connect the bus bar electrode on the back surface side of the 11th solar cell 10aa and the bus bar electrode on the light receiving surface side of the 12th solar cell 10ab.

Four of the seventh bridge wiring members 14 are provided in the first non-generating area 20a, and the remaining three are provided in the second non-generating area 20b. Each of the fifth bridge wiring member 14e through the seventh bridge wiring member 14g provided in the second non-generating area 20b extends in the x axis direction and is electrically connected to two adjacent solar cell strings 12 via the cell end wiring member 16. For example, the fifth bridge wiring member 14e is electrically connected to the 14th solar cell 10ad in the first solar cell string 12a and the 24th solar cell 10bd in the second solar cell string 12b. The cell end wiring member 16 is provided on the light receiving surface or the back surface of the solar cell 10 in a manner similar to that of the inter-cell wiring member 18.

The first bridge wiring member 14a provided in the first non-generating area 20a is connected to the 11th solar cell 10aa of the first solar cell string 12a via the cell end wiring member 16. The first bridge wiring member 14a extends from a portion of connection with the cell end wiring member 16 as far as the neighborhood of the center of the solar cell module 100 in the x axis direction. The second bridge wiring member 14b is connected to the 21th solar cell 10ba of the second solar cell string 12b via the cell end wiring member 16. The second bridge wiring member 14b is also connected to the 31st solar cell 10ca of the third solar cell string 12c via another cell end wiring member 16. Through these connections, the second bridge wiring member 14b electrically connects the second solar cell string 12b and the third solar cell string 12c.

The third bridge wiring member 14c and the fourth bridge wiring member 14d are in a mirror arrangement with respect to the second bridge wiring member 14b and the first bridge wiring member 14a in the x axis direction. Therefore, the first solar cell string 12a through the sixth solar cell string 12f are connected in series electrically. A lead wiring (not shown) is connected to each of the first bridge wiring member 14a through the fourth bridge wiring member 14d, and the lead wiring is connected to a terminal box (not shown).

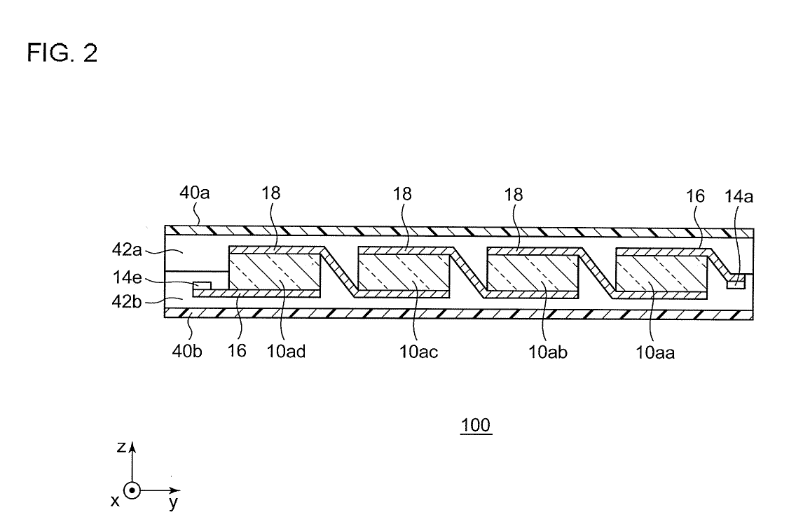

FIG. 2 is a cross-sectional view of the solar cell module 100 and is an A-A cross-sectional view of FIG. 1. The solar cell module 100 includes the 11th solar cell 10aa, the 12th solar cell 10ab, the 13th solar cell 10ac, the 14th solar cell 10ad, which are generically referred to as solar cells 10, the first bridge wiring member 14a, the fifth bridge wiring member 14e, the cell end wiring member 16, the inter-cell wiring member 18, a first protective member 40a, a second protective member 40b, which are generically referred to as protective members 40, a first encapsulant 42a, a second encapsulant 42b, which are generically referred to as encapsulants 42. The top of FIG. 2 corresponds to the light receiving surface side, and the bottom corresponds to the back surface side.

The first protective member 40a is disposed on the light receiving surface side of the solar cell module 100 and protects the surface of the solar cell module 100. The first protective member 40a is formed by using a translucent and water shielding glass, translucent plastic, etc. and is formed in a rectangular shape. In this case, it is assumed that glass is used. The first encapsulant 42a is stacked on the back surface side of the first protective member 40a. The first encapsulant 42a is disposed between the first protective member 40a and the solar cell 10 and adhesively bonds the first protective member 40a and the solar cell 10. For example, a thermoplastic resin film of polyolefin, ethylene-vinyl acetate copolymer (EVA), polyvinyl butyral (PVB), polyimide, or the like may be used as the first encapsulant 42a. A thermosetting resin may alternatively be used. The first encapsulant 42a is formed by a translucent, rectangular sheet member having a surface of substantially the same dimension as the x-y plane in the first protective member 40a.

The second encapsulant 42b is stacked on the back surface of the first encapsulant 42a. The second encapsulant 42b encapsulates the plurality of solar cells 10, the inter-cell wiring members 18, etc. between the second encapsulant 42b and the first encapsulant 42a. The second encapsulant 42b may be made of a material similar to that of the first encapsulant 42a. Alternatively, the second encapsulant 42b may be integrated with the first encapsulant 42a by heating the encapsulants in a laminate cure process.

The second protective member 40b is stacked on the back surface side of the second encapsulant 42b. The second protective member 40b protects the back surface side of the solar cell module 100 as a back sheet. For example, a resin film of polyethylene terephthalate (PET) is used as the second protective member 40b. A stack film having a structure in which an Al foil is sandwiched by resin films, or the like may be used as the second protective member 40b. An Al frame may be attached around the solar cell module 100.

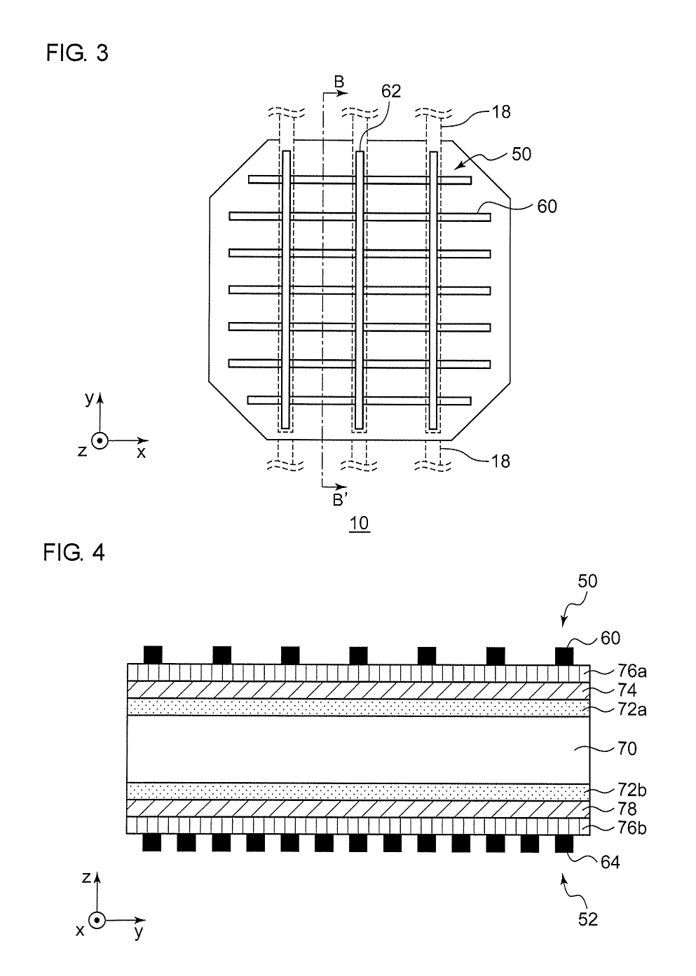

FIG. 3 is a plan view of the solar cell 10 as viewed from the light receiving surface side. The figure shows the surface on the positive direction side along the z axis of the solar cell 10 as a light receiving surface 50. The light receiving surface 50 is configured as an octagon in which longer sides and shorter sides are connected alternately but may have other shapes. For example, the shorter sides included in the octagon may not be straight lines, or the surface may be shaped in a quadrangle. A plurality of finger electrodes 60 extending in the x axis direction in a mutually parallel manner are disposed on the light receiving surface 50. Further, a plurality of (e.g., 3) bus bar electrodes 62 extending in the y axis direction are disposed to intersect (e.g., be orthogonal to) the plurality of finger electrodes 60 on the light receiving surface 50. The bus bar electrode 62 connects the plurality of finger electrodes 60 to each other. The inter-cell wiring member 18 is disposed and layered upon each of the plurality of bus bar electrodes 62. The inter-cell wiring member 18 extends in the direction of the adjacent further solar cell 10, i.e., in the y axis direction.

FIG. 4 is a cross-sectional view of the solar cell 10 and is a B-B′ cross-sectional view of FIG. 3. The solar cell 10 includes a finger electrode 60, a finger electrode 64, a semiconductor substrate 70, a first i-type layer 72a, a second i-type layer 72b, which are generically referred to as i-type layers 72, a p-type layer 74, a first transparent conductive oxide (TCO) 76a, a second TCO 76b, which are generically referred to as TCOs 76, and an n-type layer 78. The surface on the upper side in FIG. 4 is the light receiving surface 50, and the surface on the lower side in FIG. 4 is a back surface 52. The directions indicated by the expressions “upper” and “lower” are not limited to those shown in FIG. 4. The expressions may indicate arbitrary directions so long as “upper” and “lower” define opposite directions.

The semiconductor substrate 70 is made of a crystalline semiconductor material and is referred to as a crystalline semiconductor substrate. The semiconductor substrate 70 is an n-type or p-type conductive crystalline semiconductor substrate. A monocrystalline silicon substrate, a polycrystalline silicon substrate, etc. may be used. The semiconductor substrate 70 produces carrier pairs of electrons and holes in photoelectric conversion induced by absorbing incident light. It is assumed here that an n-type monocrystalline silicon substrate is used as the semiconductor substrate 70. A texture structure for improving the light absorption efficiency is provided on the surface of the semiconductor substrate 70.

The first i-type layer 72a is formed on the light receiving surface side of the semiconductor substrate 70 and is referred to as an intrinsic amorphous semiconductor layer. The first i-type layer 72a is an amorphous semiconductor layer and is a semiconductor layer that includes an amorphous phase or a microcrystalline phase in which minute crystal grains precipitate in an amorphous phase. Substantially intrinsic amorphous silicon containing hydrogen is assumed here. The first i-type layer 72a is configured to be thin to inhibit light absorption as much as possible. On the other hand, the semiconductor substrate 70 is configured to be thick enough for full surface passivation.

The p-type layer 74 is formed on the light receiving surface side of the first i-type layer 72a and is referred to as a conductive amorphous semiconductor layer. The p-type layer 74 is built such that a p-type conductive acceptor element is included, as a conductive impurity, in an amorphous semiconductor layer containing hydrogen. For example, boron is added to silicon in the p-type layer 74. The first TCO 76a is formed on the light receiving surface side of the p-type layer 74 and is referred to as a transparent conductive film layer. For example, the first TCO 76a is configured to include at least one metal oxide such as indium oxide (In₂O₃), zinc oxide (ZnO), tin oxide (SnO₂), and titanium oxide (TiO₂). A metal such as tin (Sn), zinc (Zn), tungsten (W), antimony (Sb), titanium (Ti), and cerium (Ce), gallium (Ga) or hydrogen (H) may be added to the metal oxide. The finger electrode 60 is an electrode formed on the light receiving surface side of the first TCO 76a to retrieve generated power outside. As described above, the finger electrode 60 is formed by a silver paste or the like.

The second i-type layer 72b is formed on the back surface side of the semiconductor substrate 70. The second i-type layer 72b is referred to as an intrinsic amorphous semiconductor layer like the first i-type layer 72a, or as a further intrinsic amorphous semiconductor layer. The second i-type layer 72b is formed in a manner similar to that of the first i-type layer 72a. The n-type layer 78 is formed on the back surface side of the second i-type layer 72b. The n-type layer 78 is referred to as a conductive amorphous semiconductor layer like the p-type layer 74, or as a further conductive amorphous semiconductor layer. The n-type layer 78 is built such that an n-type conductive donor element is included, as a conductive impurity having a conductivity type different from that of the impurity included in the p-type layer 74, in an amorphous semiconductor layer containing hydrogen. For example, phosphorus is added to silicon in the n-type layer 78.

The second TCO 76b is formed on the back surface side of the n-type layer 78. The second TCO 76b is referred to as a transparent conductive film layer like the first TCO 76a, or as a further transparent conductive film layer. The second TCO 76b is formed in a manner similar to that of the first TCO 76a. The finger electrode 64 is an electrode formed on the back surface side of the second TCO 76b to retrieve generated power outside. The finger electrode 64 is formed in a manner similar to that of the finger electrode 60, but the number of the finger electrodes 64 is larger than the number of the finger electrodes 60.

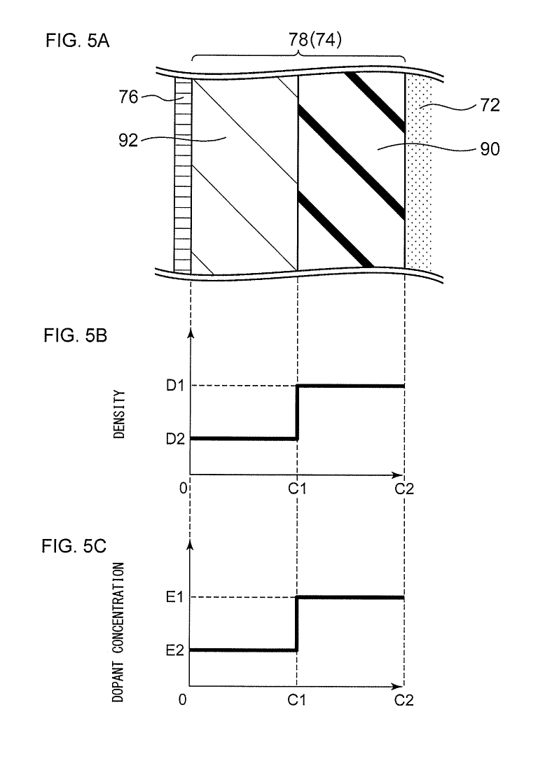

Thus, the second i-type layer 72b, the n-type layer 78, the second TCO 76b, and the finger electrode 64 are formed on the side of the semiconductor substrate 70 opposite to the first i-type layer 72a, the p-type layer 74, the first TCO 76a, and the finger electrode 60. The structure of the p-type layer 74 and the n-type layer 78 that are conductive amorphous semiconductor layers will now be described in further detail with reference to FIGS. 5A-5C.

FIGS. 5A-5C show density distribution and dopant concentration distribution in the p-type layer 74 and the n-type layer 78. FIG. 5A is an enlarged cross-sectional view of the vicinity of the TCO 76 in the structure of the solar cell 10 of FIG. 4. The figure shows the first i-type layer 72a and the second i-type layer 72b of FIG. 4 as the i-type layer 72 and shows the first TCO 76a and the second TCO 76b as the TCO 76. The figure also shows the n-type layer 78 or the p-type layer 74 sandwiched by the i-type layer and the TCO. The description here assumes the n-type layer 78, but the p-type layer 74 is similarly formed.

The n-type layer 78 has a two-layer structure including a remote portion 90 and a proximate portion 92. The proximate portion 92 is formed in a portion closer to the TCO 76 than the remote portion 90. Therefore, the TCO 76, the proximate portion 92, the remote portion 90, and the i-type layer 72 are stacked in the stated order from the outer side of the solar cell 10. What is common to the remote portion 90 and the proximate portion 92 is that both include an n-type conductive donor element in an amorphous semiconductor layer containing hydrogen. Meanwhile, the difference between the remote portion 90 and the proximate portion 92 is shown in FIGS. 5B-5C.

FIG. 5B shows the density in the n-type layer 78 in the remote portion 90 and in the proximate portion 92. The horizontal axis represents a distance from the TCO 76. The boundary between the proximate portion 92 and the remote portion 90 is denoted by “C1”, and the boundary between the remote portion 90 and the i-type layer 72 is denoted by “C2”. The interval between distances “0” and “C1” is the proximate portion 92, and the interval between distances “C1” and “C2” is the remote portion 90. The vertical axis represents density. The density is represented by the weight of the n-type layer 78 per a unit volume. As illustrated, the density in the proximate portion 92 of the n-type layer 78 (hereinafter, referred to as “density in the proximate portion 92”) is denoted by “D2”, and the density in the remote portion 90 of the n-type layer 78 (hereinafter, referred to as “density in the remote portion 90”) is denoted by “D1”. It should be noted that D2<D1, and the density changes in such a manner as to define a step across the boundary C1.

By way of example, the density “D2” in the proximate portion 92 is configured to be 0.8 times-0.99 times the density “D1” in the remote portion. In the proximate portion 92 with a smaller density such as this, the defect density will be larger than in the remote portion 90. An increase in the defect density induces formation of a defect level. This makes electrons at the defect level movable and reduces the contact resistance as a result. In other words, the contact resistance between the TCO 76 and the n-type layer 78 is reduced by decreasing the density in the proximate portion 92. If the density in the proximate portion 92 is too small, on the other hand, the conductivity will be lowered so that the density in the proximate portion 92 is configured to be in the aforementioned range. In the p-type layer 74, the density “D2” in the proximate portion 92 is configured to be 0.8 times-0.99 times the density “D1” in the remote portion 90.

FIG. 5C shows the dopant impurity concentration in the remote portion 90 and in the proximate portion 92. As described above, the impurity in this case will be the donor. The horizontal axis is as shown in FIG. 5B. The vertical axis represents the dopant concentration. The dopant concentration is represented by the number of impurities relative to the number of silicon atoms. As illustrated, the dopant concentration in the proximate portion 92 is denoted by “E2”, and the dopant concentration in the remote portion 90 is denoted by “E1”. It should be noted that E2<E1, and the dopant concentration also changes so as to define a step across the boundary C1. The advantage of configuring the dopant concentration to be smaller in the proximate portion 92 will be discussed in describing the method of manufacturing the solar cell 10.

Generally, a small dopant impurity concentration in the n-type layer 78 results in a larger electric resistance. However, the contact resistance is decreased by decreasing the density in the proximate portion 92. Therefore, an increase in the electric resistance caused by reduction in the dopant concentration does not present a problem by decreasing the dopant concentration in such a manner that an increase in the electric resistance is smaller than a decrease in the contact resistance.

As described above, the remote portion 90 and the proximate portion 92 may be disposed in the p-type layer 74 as in the n-type layer 78. In that case, the impurity will be the acceptor. Further, the remote portion 90 and the proximate portion 92 in the p-type layer 74 and the n-type layer 78 may be referred to as the first portion and the second portion, respectively, and the remote portion 90 and the proximate portion 92 in the n-type layer 78 may be referred to as the third portion and the fourth portion, respectively. Further, the remote portion 90 and the proximate portion 92 may be formed only in one of the p-type layer 74 and the n-type layer 78.

It has been assumed so far that the two-layer structure of the remote portion 90 and the proximate portion 92 forms the p-type layer 74 or the n-type layer 78, and the density and the dopant concentration are smaller in the proximate portion 92 than in the remote portion 90. The density and the dopant concentration both change to define a step across the boundary between the remote portion 90 and the proximate portion 92. However, the density and the dopant concentration may change as described below on the condition that the closer to the TCO 76, the smaller the density and the concentration.

(1) A multilayer structure including three or more layers may be used instead of the two-layer structure. The position where the density changes and that of the dopant concentration may differ. This allows the controlling the density and the dopant concentration in an independent manner. For example, the layer with a smaller density may be present only in the vicinity of the boundary with the TCO 76 for the purpose of improving the contact resistance between the n-type layer 78 and the TCO 76 by using the defect level. For the purpose of reducing the impurity attached to the mask, however, the layer with a lower dopant concentration may be not necessarily be disposed only in the vicinity of the boundary but may be disposed in a wider range.

(2) The stepwise change between the remote portion 90 and the proximate portion 92 may be slopewise in the vicinity of the boundary.

(3) The change across the remote portion 90 and the proximate portion 92 may not be stepwise but may be continuously slopewise.

A description will now be given of a method of manufacturing the solar cell module 100. A description will be given of (A) a method of manufacturing a solar cell 10 and then (B) a method of manufacturing a solar cell module 100.

(A) Method of Manufacturing the Solar Cell 10

The solar cell 10 is manufactured by using plasma chemical vapor deposition (PECVD) method, catalytic CVD (cat-CVD) method, sputtering method, etc. It is assumed here that RF plasma CVD method exemplifying plasma CVD method is used. Also, the step of forming the second i-type layer 72b, the n-type layer 78, and the second TCO 76b successively on the back surface side of the semiconductor substrate 70 will be described below.

(A-1) First, the semiconductor substrate 70 is prepared, and the semiconductor substrate 70 is cleaned by an aqueous solution of hydrofluoric acid (HF) or an RCA cleaning liquid. A texture structure may be formed on the light receiving surface or the back surface of the substrate by using an alkaline etching liquid such as an aqueous solution of potassium hydroxide.

(A-2) The semiconductor substrate 70 is placed in a chamber to form the n-type layer 78. Following this step, an RF high-frequency power is applied to a parallel flat-plate electrode sandwiching the semiconductor substrate 70 while a silicon-containing gas such as silane (SiH₄) and hydrogen as a diluent gas are being supplied, thereby turning the gases into a plasma. The plasma is supplied to the deposition surface of the semiconductor substrate 70 that is heated. This forms the second i-type layer 72b on the back surface of the semiconductor substrate 70. During deposition, the temperature is set to be about 150-250° C., and the RF power density is set to be about 1-30 mW/cm².

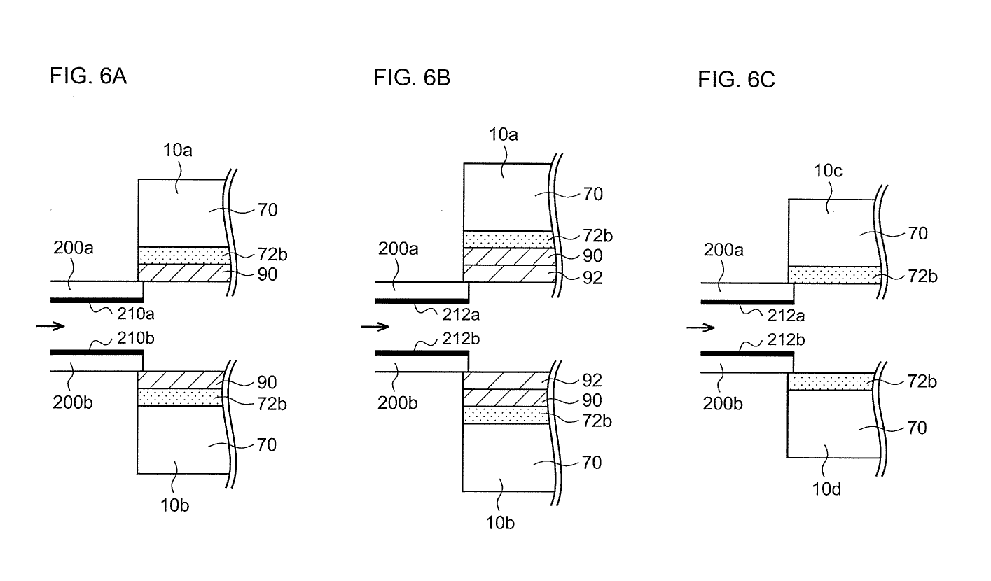

(A-3) Subsequently, a gas such as phosphine (PH₃) including an n-type element is added to a silicon-containing gas such as silane (SiH₄). The resultant gas is diluted by hydrogen, supplied accordingly, and turned into a plasma by applying an RF high-frequency power to the parallel flat-plate electrode before being supplied to the decomposition surface of the semiconductor substrate 70 that is heated. In this way, the n-type layer 78 is formed on the back surface side of the second i-type layer 72b. During deposition, the temperature is set to about 150-250° C., and the RF power density is set to be about 1-30 mW/cm². As described above, the n-type layer 78 has a two-layer structure of the remote portion 90 and the proximate portion 92. The method of manufacturing the n-type layer 78 will be described with reference to FIGS. 6A-6C. FIGS. 6A-6C show an outline of the steps of manufacturing the solar cell 10.

Referring to FIG. 6A, at least a portion of the first solar cell 10a is coated with a first mask 200a, at least a portion of the second solar cell 10b is coated with a second mask 200b, and the first solar cell 10a and the second solar cell 10b are placed in the chamber one above the other. At this stage, the second i-type layer 72b is formed on the back surface side of the semiconductor substrate 70 in the first solar cell 10a and the second solar cell 10b, as described in (A-2). By supplying a gas in the direction of the arrow, the remote portion 90 is formed on the back surface side of the second i-type layer 72b. In this process, a first impurity 210a is attached to the surface of the first mask 200a, and a second impurity 210b is attached to the surface of the second mask 200b. The first impurity 210a and the second impurity 210b are included in the gas.

FIG. 6B shows a step that follows the step of FIG. 6A. In this step, the proximate portion 92 is formed on the back surface side of the remote portion 90 by using a deposition speed higher than the deposition speed for forming the remote portion 90. By using a higher deposition speed, the density in the proximate portion 92 will be smaller than the density in the remote portion 90. The deposition speed for forming the proximate portion 92 is configured to be 1.01 times-5.00 times the deposition speed for forming the remote portion 90. The deposition speed can be controlled by regulating the RF power density and the pressure.

In that process, the gas flow ratio is configured to be lower than in the case of forming the remote portion 90. By using a lower gas flow ratio, the dopant impurity concentration in the proximate portion 92 will be smaller than the dopant impurity concentration in the remote portion 90. As in the case above, a first impurity 212a is attached to the surface of the first mask 200a, and a second impurity 212b is attached to the surface of the second mask 200b. Since the density of impurity included in the gas is lower, the amount of the first impurity 212a and the second impurity 212b is lower as compared to that of the first impurity 210a and the second impurity 210b.

FIG. 6C shows a state in which the third solar cell 10c and the fourth solar cell 10d, which are unprocessed, are placed in the chamber after the first solar cell 10a and the second solar cell 10b are manufactured. The step in (A-2) forms the second i-type layer 72b on the back surface side of the semiconductor substrate 70. In this process, the first impurity 212a attached to the first mask 200a and the second impurity 212b attached to the second mask 200b are knocked off by the gas supplied and are incorporated into the second i-type layer 72b. However, the amount of the first impurity 212a and the second impurity 212b is smaller than the amount of the first impurity 210a and the second impurity 210b so that the amount of impurity incorporated into the second i-type layer 72b is reduced. This inhibits the output of the solar cell 10 from being lowered as a result of the impurity being mixed in the i-type layer 72.

(A-4) The semiconductor substrate 70 on which the second i-type layer 72b and the n-type layer 78 are stacked is taken out from the chamber and is placed in a further chamber for forming the p-type layer 74. Steps similar to those of (A-2) and (A-3) are repeated there. For formation of the p-type layer 74, a gas such as diborane (B₂H₆) that includes a p-type element is added to a silicon-containing gas such as silane (SiH₄). The resultant gas is diluted by hydrogen and turned into a plasma by applying an RF high-frequency power to the parallel flat-plate electrode. The plasma is supplied to the decomposition surface of the semiconductor substrate 70 that is heated. The deposition speed for forming the proximate portion 92 in the p-type layer 74 is configured to be 1.01 times-7.00 times the deposition speed for forming the remote portion 90. According to the foregoing description, the p-type layer 74 is formed after the n-type layer 78 is formed. Alternatively, the n-type layer 78 may be formed after the p-type layer 74 is formed.

(A-5) The second TCO 76b is formed on the back surface side of the n-type layer 78, and the first TCO 76a is formed on the light receiving surface side of the p-type layer 74. For formation of the TCO 76, a thin film formation method such as deposition, plasma CVD, and sputtering is used.

(B) Method of Manufacturing the Solar Cell Module 100

First, the stack is produced by successively layering the first protective member 40a, the first encapsulant 42a, the solar cell 10, etc. the second encapsulant 42b, and the second protective member 40b from the positive direction side toward the negative direction side along the z axis. This is followed by a laminate cure process performed for the stack. In this process, air is drawn from the stack, and the stack is heated and pressurized so as to be integrated. In vacuum lamination in the laminate cure process, the temperature is set to about 150°, as mentioned above.

According to the embodiment of the present disclosure, the density in the proximate portion 92 in the p-type layer 74, the n-type layer 78 is configured to be smaller than the density in the remote portion 90 so that the defect density in the proximate portion 92 is configured to be larger than the defect density in the remote portion 90. Further, since the defect density is increased, the defect level is formed and the contact resistance is reduced. Since the density in the remote portion 90 is configured to be larger than the density in the proximate portion 92, the activation rate and the conductivity in the film are improved. Since the dopant concentration in the proximate portion 92 is configured to be smaller than the dopant concentration in the remote portion 90, the amount of impurity attached to the mask 200 when the solar cell 10 is manufactured is reduced. Since the amount of impurity attached to the mask 200 is reduced, the amount of impurity included in the i-type layer 72 when a new solar cell 10 is manufactured is reduced. Since the amount of impurity included in the i-type layer 72 is reduced, the output of the solar cell 10 is inhibited from being lowered.

Since the contact resistance is reduced by configuring the density in the proximate portion 92 to be smaller than the density in the remote portion 90, an increase in the electric resistance is inhibited even if the dopant concentration in the proximate portion 92 is configured to be smaller than the dopant concentration in the remote portion 90. Further, the deposition speed for forming the proximate portion 92 is configured to be higher than the deposition speed for forming the remote portion 90, the density in the proximate portion 92 is configured to be smaller than the density in the remote portion 90. Since the deposition speed for forming the proximate portion 92 is configured to be 1.01 times-5.00 times the deposition speed for forming the remote portion 90, the contact resistance is reduced.

A summary of the embodiment is given below. A solar cell 10 according to an embodiment of the present disclosure includes: a semiconductor substrate 70; an i-type layer 72 formed on a side of one surface of the semiconductor substrate 70; a p-type layer 74, an n-type layer 78 formed on the i-type layer 72 and including a conductive impurity; and a TCO 76 formed on the p-type layer 74, the n-type layer 78. A density in a proximate portion 92 of the p-type layer 74, the n-type layer 78 closer to the TCO 76 than a remote portion 90 of the p-type layer 74, the n-type layer 78 is smaller than a density in the remote portion 90.

A dopant concentration in the proximate portion 92 of the p-type layer 74, the n-type layer 78 is smaller than a dopant concentration in the remote portion 90.

The solar cell may further include a further i-type layer 72, a n-type layer 78 including a conductive impurity, and a further TCO 76. The further i-type layer 72, the n-type layer 78, and the further TCO 76 are formed on a side of the semiconductor substrate 70 opposite to the i-type layer 72, the p-type layer 74, and the TCO 76, a conductivity type of the impurity included in the n-type layer 78 is different from a conductivity type of the impurity included in the p-type layer 74, and a density in a fourth portion of the n-type layer 78 closer to the further TCO 76 than a third portion of the n-type layer 78 is smaller than a density in the third portion.

Another embodiment of the present disclosure relates to a method of manufacturing the solar cell 10. The method includes: forming an i-type layer 72 on a side of one surface of a semiconductor substrate 70 masked at least in part; forming a p-type layer 74, an n-type layer 78 including a conductive impurity on the i-type layer 72; and forming a TCO 76 on the p-type layer 74, the n-type layer 78. A deposition speed for forming a proximate portion 92 of the p-type layer 74, the n-type layer 78 closer to the TCO 76 than a remote portion 90 of the p-type layer 74, the n-type layer 78 is higher than a deposition speed for forming the remote portion 90.

The deposition speed for forming the proximate portion 92 of the p-type layer 74, the n-type layer 78 is 1.01 times-5.00 times the deposition speed for forming the remote portion 90.

Described above is an explanation based on an exemplary embodiment. The embodiment is intended to be illustrative only and it will be understood by those skilled in the art that various modifications to constituting elements and processes could be developed and that such modifications are also within the scope of the present invention.

In the embodiment, the solar cell 10 is assumed to be a hetero-junction solar cell. Alternatively, the solar cell 10 may be, for example, a back-contact solar cell. According to this variation, the scope of application of the embodiment is expanded.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell comprising:
a crystalline semiconductor substrate;
an intrinsic amorphous semiconductor layer formed on a side of one surface of the crystalline semiconductor substrate;
a conductive amorphous semiconductor layer formed on the intrinsic amorphous semiconductor layer and including a conductive impurity; and
a transparent conductive film layer formed on the conductive amorphous semiconductor layer, wherein
a density in a second portion of the conductive amorphous semiconductor layer closer to the transparent conductive film layer than a first portion of the conductive amorphous semiconductor layer is smaller than a density in the first portion.

2. The solar cell according to claim 1, wherein
a dopant concentration in the second portion of the conductive amorphous semiconductor layer is smaller than a dopant concentration in the first portion.

3. The solar cell according to claim 1, further comprising:
a further intrinsic amorphous semiconductor layer;
a further conductive amorphous semiconductor layer including a conductive impurity; and
a further transparent conductive film layer, wherein
the further intrinsic amorphous semiconductor layer, the further conductive amorphous semiconductor layer, and the further transparent conductive film layer are formed on a side of the crystalline semiconductor substrate opposite to the intrinsic amorphous semiconductor layer, the conductive amorphous semiconductor layer, and the transparent conductive film layer,
a conductivity type of the impurity included in the further conductive amorphous semiconductor layer is different from a conductivity type of the impurity included in the conductive amorphous semiconductor layer, and
a density in a fourth portion of the further conductive amorphous semiconductor layer closer to the further transparent conductive film layer than a third portion of the further conductive amorphous semiconductor layer is smaller than a density in the third portion.

4. The solar cell according to claim 2, further comprising:
a further intrinsic amorphous semiconductor layer;
a further conductive amorphous semiconductor layer including a conductive impurity; and
a further transparent conductive film layer, wherein
the further intrinsic amorphous semiconductor layer, the further conductive amorphous semiconductor layer, and the further transparent conductive film layer are formed on a side of the crystalline semiconductor substrate opposite to the intrinsic amorphous semiconductor layer, the conductive amorphous semiconductor layer, and the transparent conductive film layer,
a conductivity type of the impurity included in the further conductive amorphous semiconductor layer is different from a conductivity type of the impurity included in the conductive amorphous semiconductor layer, and
a density in a fourth portion of the further conductive amorphous semiconductor layer closer to the further transparent conductive film layer than a third portion of the further conductive amorphous semiconductor layer is smaller than a density in the third portion.

5. A method of manufacturing a solar cell comprising:
forming an intrinsic amorphous semiconductor layer on a side of one surface of a crystalline semiconductor substrate masked at least in part;
forming a conductive amorphous semiconductor layer including a conductive impurity on the intrinsic amorphous semiconductor layer; and
forming a transparent conductive film layer on the conductive amorphous semiconductor layer, wherein
a deposition speed for forming a second portion of the conductive amorphous semiconductor layer closer to the transparent conductive film layer than a first portion of the conductive amorphous semiconductor layer is higher than a deposition speed for forming the first portion.

6. The method of manufacturing a solar cell according to claim 5, wherein
the deposition speed for forming the second portion of the conductive amorphous semiconductor layer is 1.01 times-5.00 times the deposition speed for forming the first portion.
